(19) United States
(12) Patent Application Publication
(10) Pub. No.: US 2023/0138598 A1
(43) Pub. Date: May 4, 2023

(54) FOLDING DISPLAY APPARTUS, MOBILE TERMINAL, AND DISPLAY METHOD

(71) Applicant: SHANGHAI WINGTECH ELECTRONIC TECHNOLOGY CO., LTD., Shanghai (CN)

(72) Inventor: Wei FENG, Shanghai (CN)

(21) Appl. No.: 17/912,946

(22) PCT Filed: Nov. 27, 2020
(86) PCT No.: PCT/CN2020/132051

§ 371 Date: Sep. 20, 2022

(30) Foreign Application Priority Data
Apr. 17, 2020 (CN) 202010304731.0

(51) Int. Cl. H05K 5/02

(52) U.S. Cl. CPC H05K 5/0217

(57) ABSTRACT

A foldable display device includes a housing and a flexible screen; the flexible screen is used for displaying an object, and includes a first part, a second part and a bendable third part; the housing includes a front side of the housing, and the first part is slidably supported on the front side of the housing; and the housing further includes a holding tank extending in parallel with the front side of the housing, and when the third part is bent, the second part is capable of sliding into the holding tank. The mobile terminal includes the above foldable display device. The display method includes the steps of detecting a state of a flexible screen; and respectively controlling display of a first part, a second part and a third part according to the state.

This application claims the priority of the Chinese patent application filed on Apr. 17, 2020 before the Chinese Patent Office with the application number of 202010304731.0, the entire contents of which are incorporated herein by reference.

### TECHNICAL FIELD

The present application relates to the technical field of electronic apparatuses, and more particularly, to a foldable display device, a mobile terminal and a display method.

### BACKGROUND

Mobile terminals with foldable screens have begun to appear, and major manufacturers have launched their own products. However, from the view of market, foldable flexible screens of current products are all combined with apparatuses, which are relatively thick in overall thickness, giving users a bad experience.

The foldable screen will not display all areas for a long time when in use, so it is necessary to protect the parts that are not frequently displayed.

### SUMMARY

The present application provides a foldable display device, a mobile terminal and a display method, so as to protect a flexible screen part which is not frequently displayed.

The present application provides a foldable display device, including:

a flexible screen, wherein the flexible screen is configured for displaying an object, and includes a first part and a second part, and a bendable third part between the first part and the second part; and

a housing, wherein the housing includes a front side of the housing, and the first part is slidably supported on the front side of the housing; and the housing further includes a holding tank extending in parallel with the front side of the housing, and when the third part is bent, the second part is capable of sliding into the holding tank.

The foldable display device can partially hold the flexible screen into the holding tank, thus avoiding the part from contacting with the outside world so as to protect the part.

As an optional solution of the foldable display device above, a sensor and a controller are further included, wherein the sensor is on the third part to detect a state of the third part, and the controller controls display of the first part, the second part and the third part according to the state.

Since main deformation of the flexible screen occurs in the third part, setting the sensor in the third part can timely and accurately acquire a bent state of the flexible screen, and acquire the state of the flexible screen through the sensor and control a display area of the flexible screen, thus enriching a display state of the flexible screen.

As an optional solution of the foldable display device above, the sensor is a bending sensor.

As an optional solution of the foldable display device above, the flexible screen is provided with supporting mechanisms, the front side of the housing and the holding tank are provided with guide parts extending in a slide direction, and the supporting mechanisms are slidably connected to the guide parts.

As an optional solution of the foldable display device above, the guide parts are arranged on both sides of the front side of the housing and the holding tank in the slide direction, the supporting mechanisms are arranged on both sides of the flexible screen in the slide direction, and the guide parts are covered on the supporting mechanisms.

The two sides of the flexible screen are provided with the supporting mechanisms and covered by the guide parts, so that a certain dustproof effect can be achieved.

As an optional solution of the foldable display device above, the supporting mechanism is arranged on a non-display surface of the flexible screen, the guide part is one of a rib and a chute, and the supporting mechanism is provided with the other of the rib and the chute.

The present application further provides a mobile terminal, including the foldable display device above.

The present application further provides a display method, using the foldable display device above, including the steps of:

detecting a state of the third part; and

respectively controlling display of the first part, the second part and the third part according to the state.

As an optional solution of the display method above, the state includes a bent state and a flattened state.

As an optional solution of the display method above, the respectively controlling the display of the first part, the second part and the third part according to the state includes:

when the state is the bent state, controlling the first part and/or the third part to display and controlling the second part not to display; and

when the state is the flattened state, controlling the first part, the second part and the third part to display simultaneously.

The mobile terminal provided by the present application can partially hold the screen into the holding tank, thus avoiding the part from contacting with the outside world so as to protect the part. By obtaining the state of the third part of the flexible screen, the display area of the flexible screen is controlled, thus enriching the display state of the flexible screen.

### BRIEF DESCRIPTION OF THE DRAWINGS

In order to illustrate the technical solutions in the embodiments of the present application more clearly, the accompanying drawings used in the description of the embodiments will be briefly described below. The accompanying drawings in the following description only illustrate some embodiments of the present application. Those having ordinary skills in the art can obtain other drawings according to these drawings.

FIG. 1 is a schematic structural diagram of a mobile terminal in a storage state according to an embodiment of the present application;

FIG. 2 is a schematic structural diagram of a mobile terminal in an unfolded process according to the embodiment of the present application;

FIG. 3 is a schematic structural diagram of another mobile terminal in an unfolded process according to an embodiment of the present application;

FIG. 4 is a schematic structural diagram of yet another mobile terminal in an unfolded process according to an embodiment of the present application;

FIG. 5 is a schematic structural diagram when a flexible screen and a housing of a mobile terminal according to an embodiment of the present application are matched; and

FIG. 6 is a schematic structural diagram when a flexible screen and a housing of a mobile terminal according to another embodiment of the present application are matched.

In the Drawings:

1 refers to housing; 2 refers to flexible screen; 3 refers to sensor; 1A refers to front side of housing; 1B refers to back side of housing; 1C refers to holding tank; 10 refers to guide part; 20 refers to supporting mechanism, 21 refers to first part; 22 refers to second part; and 23 refers to third part.

### DETAILED DESCRIPTION

The present application is described below with reference to the accompanying drawings and the embodiments. The embodiments described herein are merely illustrative of the present application and are not intended to limit the present application. For ease of description, the accompanying drawings only show a part of the structure related to the present application, but not all of the structure.

In the description of the present invention, unless expressly stipulated and defined otherwise, terms such as “connected”, “connection”, and “fixing” should be understood broadly, for example, the connection may be fixed connection, detachable connection or integrated connection; may be mechanical connection, and may also be electrical connection; and may be direct connection, may also be indirect connection through an intermediate medium, and may also be internal communication of two elements or interaction relationship of two elements. For those having ordinary skills in the art, the meaning of the above-mentioned terms in the application can be understood according to specific situations.

In the present invention, unless expressly stipulated and defined otherwise, the first feature “over” or “under” the second feature may include that the first and second features are in direct contact, and may also include that the first and second features are not directly contacted, but contacted through other intermediate features. Moreover, the first feature “over”, “above” and “upper” the second feature includes that the first feature is right above or diagonally above the second feature, or simply means that a horizontal height of the first feature is higher than that of the second feature. The first feature “under”, “below” and “lower” the second feature includes that the first feature is right below or diagonally below the second feature, or only means that the horizontal height of the first feature is less than that of the second feature.

In the description of the embodiments, the orientation or positional relationship indicated by the terms “upper”, “lower”, “right” and the like is based on the orientation or positional relationship shown in the drawings, only for the convenience of describing and simplifying the operations, and does not indicate or imply that the indicated device or element must have a specific orientation, or be constructed and operated in a specific orientation. Therefore, the terms should not be construed as limiting the present application. Moreover, the terms “first” and “second” are only used to distinguish between descriptions and have no special meaning.

The present application provides a foldable display device.

As shown in FIG. 1 to FIG. 4, the foldable display device includes a housing 1 and a flexible screen 2. The housing 1 is provided with a front side 1A of the housing and a back side 1B of the housing, and a holding tank 1C is provided between the front side 1A of the housing and the back side 1B of the housing. The holding tank 1C is parallel to the front side 1A of the housing. The flexible screen 2 is configured for displaying an object, and the flexible screen 2 includes a first part, a second part and a bendable third part 23 between the first part 21 and the second part 22. The first part 21 is slidably supported on the front side 1A of the housing. The third part 23 is connected between the first part 21 and the second part 22. When the third part 23 is bent, the second part 22 is capable of sliding into the holding tank 1C.

It should be noted that in this embodiment, the third part 23 is arranged on a right side of the foldable display device, that is, the flexible screen 2 can slide from left to right.

The third part 23 may also be arranged at a bottom of the foldable display device in a length direction. In this case, the flexible screen 2 can slide out from the bottom of the foldable display device in the length direction, but the present application is not limited to this.

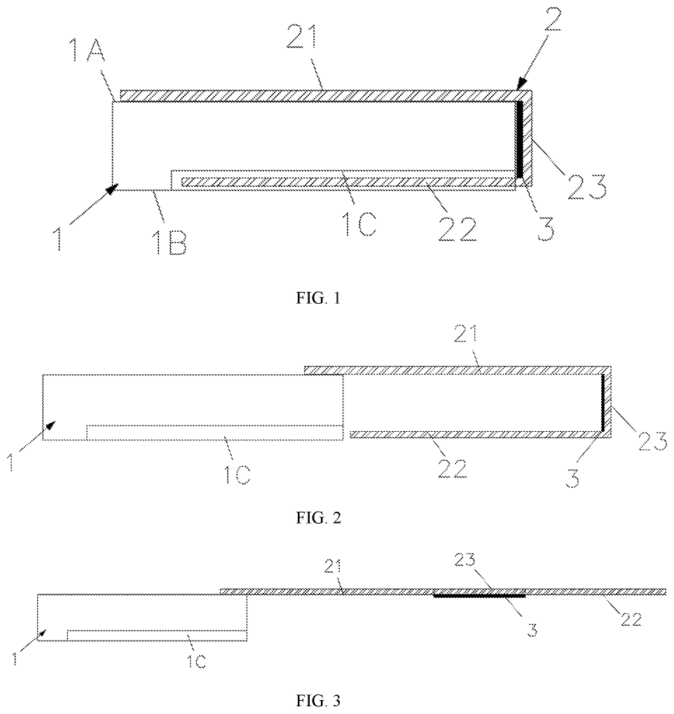

As shown in FIG. 1, the first part 21 is arranged on the front side 1A of the housing, and the second part 22 is entirely arranged in the holding tank 1C. As shown in FIG. 2 to FIG. 4, the third part 23 and the second part 22 gradually slide to the right, and the second part 22 is driven to protrude out from the holding tank 1C. Finally, the second part 22, the third part 23 and the first part 21 are on the same plane.

It should be noted that a length of the first part 21 is greater than a length of the second part 22, so that when the first part 21 slides to a tail end, the second part 22 is fully extended protruded out from the holding tank 1C. In this embodiment, the length of the first part 21 corresponds to a length of the front side 1A of the housing, while the length of the second part 22 is ⅘ of the length of the first part 21.

The mobile terminal further includes a sensor 3 and a controller. The sensor 3 is on the third part 23 to obtain a state of the third part 23, and the controller controls display of the first part 21, the second part 22 and the third part 23 according to the state.

In this embodiment, the sensor 3 is a bending sensor.

When the sensor 3 determines that the third part 23 is in a bent state, a display state of the foldable display device may be set as follows: in a first case, contents are displayed on the first part 21 only; in a second case, contents are displayed on the third part 23 only; and in a third case, contents are simultaneously displayed on the first part 23 and the third part 23. In other words, when the third part 23 is in the bent state, contents are not displayed on the second part 22 in the holding tank 1C.

When the sensor 3 determines that the foldable display device is in a flattened state, the display state of the foldable display device may be set as follows: contents are simultaneously displayed on the first part 21, the third part 23 and the second part 22.

It should be noted that although the second part 22 may not be coplanar with the first part 21, due to a factor of display effects, a user is allowed to continuously bend the third part 23, so that the first part 21 and the second part 22 are on the same horizontal plane, that is, an included angle between the first part and the second part is 180 degrees.

In this embodiment, the bent state means that the third part 23 makes the included angle between the first part 21 and the second part 22 range from 0 degree to 170 degrees, and the flattened state means that the third part 23 makes the included angle between the first part 21 and the second part 22 range from 0 degree to 180 degrees.

As shown in FIG. 5 and FIG. 6, the flexible screen 2 is provided with supporting mechanisms 20. The supporting mechanisms 20 improve strength of the flexible screen 2. The front side 1A of the housing and the holding tank 1C are provided with guide parts 10 extending in a slide direction, and the supporting mechanisms 20 are slidably connected to the guide parts 10.

It should be noted that the flexible screen 2 further includes a retaining mechanism (not shown in the figure) that can keep at any angle when the retaining mechanism bends. In this embodiment, the retaining mechanism is arranged in the third part 23 of the flexible screen 2, and a damping hinge is employed as the retaining mechanism.

With reference to FIG. 1 to FIG. 5, the guide parts 10 are arranged on both sides of the front side 1A of the housing and the holding tank 1C in the slide direction, and the supporting mechanisms 20 are arranged on both sides of the flexible screen 2 in the slide direction, and the guide parts 10 are covered on the supporting mechanisms 20. Both sides of the flexible screen 2 are always arranged in the guide parts 10, thereby improving a dustproof effect of the foldable display device.

With reference to FIG. 1 to FIG. 4 and FIG. 6, in another embodiment, the supporting mechanism 20 is arranged on a non-display surface of the flexible screen, the guide part 10 is one of a rib and a chute, and the supporting mechanism 20 is provided with the other of the rib and the chute. In this embodiment, the guide part 10 is a groove, and the supporting mechanism 20 is provided with a rib.

Compared with the embodiment of FIG. 5, the flexible screen 2 shown in FIG. 6 has no blocking edges, which maximizes the display area of the flexible screen 2.

It should be noted that the flexible screen 2 can be slided by software, for example, may be controlled by virtual keys displayed on the flexible screen 2, or may be slided manually.

The present application further provides a mobile terminal, and the mobile terminal is provided with the foldable display device above.

The present application further provides a display method, using the foldable display device above, including the steps of:

detecting a state of the third part 23; and

respectively controlling display of the first part 21, the second part 22 and the third part 23 according to the state.

It should be noted that the state includes the bent state and the flattened state above.

A working principle of the mobile terminal of the present application is as follows:

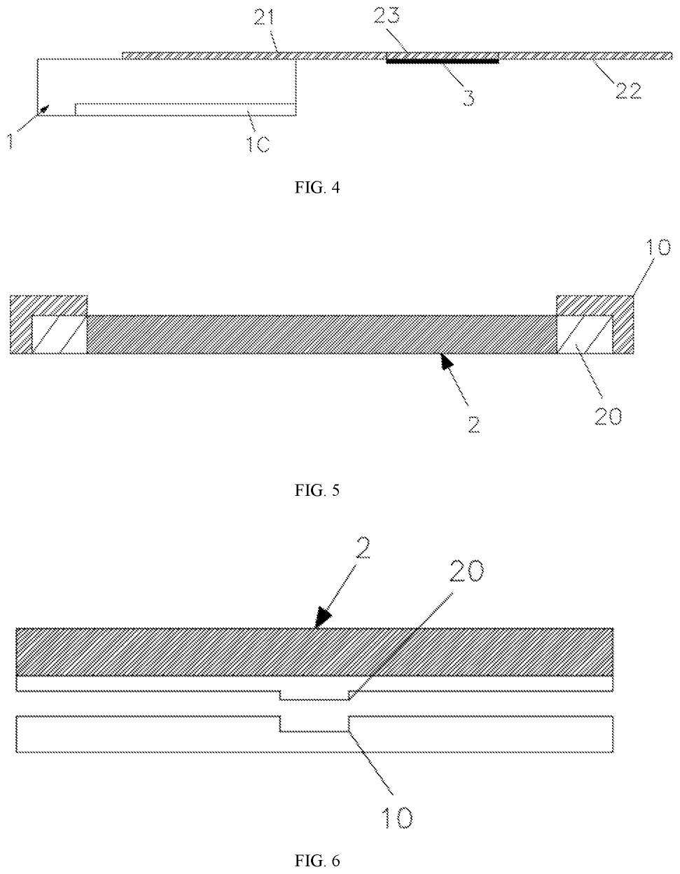

In the bent state as shown in FIG. 1, the flexible screen 2 presents a U-shaped structure, the first part 21 is arranged on the front side 1A of the housing, and the second part 22 is held in the holding tank 1C. The sensor 3 detects that the third part 23 is in the bent state, and only controls the first part 21 and/or the third part 23 to display, and controls the second part 22 not to display. As shown in FIG. 2, the first part 21 is slided to make the second part 22 slide out of the holding tank 1C, then the third part 23 is continuously bent, so that the second part 22, the third part 23 and the first part 21 are on the same plane (the flattened state shown in FIG. 3). When the sensor 3 detects that the third part 23 is in the flattened state, the first part 21, the third part 23 and the second part 22 are controlled to display contents simultaneously. Finally, the first part 21 is slided to the home position as shown in FIG. 4 to achieve the best use effect.

1. A foldable display device, comprising:
a flexible screen, wherein the flexible screen is configured for displaying an object, and comprises a first part and a second part, and a bendable third part between the first part and the second part; and
a housing, wherein the housing comprises a front side of the housing, and the first part is slidably supported on the front side of the housing; and the housing further comprises a holding tank extending in parallel with the front side of the housing, and when the third part is bent, the second part is capable of sliding into the holding tank.

2. The foldable display device according to claim 1, further comprising a sensor and a controller, wherein the sensor is on the third part to detect a state of the third part, and the controller controls display of the first part, the second part and the third part according to the state.

3. The foldable display device according to claim 2, wherein the sensor is a bending sensor.

4. The foldable display device according to claim 1, characterized in that, wherein the flexible screen is provided with supporting mechanisms, the front side of the housing and the holding tank are provided with guide parts extending in a slide direction, and the supporting mechanisms are slidably connected to the guide parts.

5. The foldable display device according to claim 4, wherein the guide parts are arranged on both sides of the front side of the housing and the holding tank in the slide direction, the supporting mechanisms are arranged on both sides of the flexible screen in the slide direction, and the guide parts are covered on the supporting mechanisms.

6. The foldable display device according to claim 4, wherein the supporting mechanism is arranged on a non-display surface of the flexible screen, the guide part is one of a rib and a chute, and the supporting mechanism is provided with the other of the rib and the chute.

7. A mobile terminal, comprising the foldable display device according to claim 1.

8. A display method, using the foldable display device according to claim 1, comprising the steps of:
detecting a state of the third part; and
respectively controlling display of the first part, the second part and the third part according to the state.

9. The display method according to claim 8, wherein the state comprises a bent state and a flattened state.

10. The display method according to claim 9, wherein the respectively controlling the display of the first part, the second part and the third part according to the state comprises:
when the state is the bent state, controlling the first part and/or the third part to display and controlling the second part not to display; and
when the state is the flattened state, controlling the first part, the second part and the third part to display simultaneously.

11. The foldable display device according to claim 2, wherein the flexible screen is provided with supporting mechanisms, the front side of the housing and the holding tank are provided with guide parts extending in a slide direction, and the supporting mechanisms are slidably connected to the guide parts.

12. The foldable display device according to claim 11, wherein the guide parts are arranged on both sides of the front side of the housing and the holding tank in the slide direction, the supporting mechanisms are arranged on both sides of the flexible screen in the slide direction, and the guide parts are covered on the supporting mechanisms.

13. The foldable display device according to claim 11, wherein the supporting mechanism is arranged on a non-display surface of the flexible screen, the guide part is one of a rib and a chute, and the supporting mechanism is provided with the other of the rib and the chute.

14. The foldable display device according to claim 3, wherein the flexible screen is provided with supporting mechanisms, the front side of the housing and the holding tank are provided with guide parts extending in a slide direction, and the supporting mechanisms are slidably connected to the guide parts.

15. The foldable display device according to claim 14, wherein the guide parts are arranged on both sides of the front side of the housing and the holding tank in the slide direction, the supporting mechanisms are arranged on both sides of the flexible screen in the slide direction, and the guide parts are covered on the supporting mechanisms.

16. The foldable display device according to claim 14, wherein the supporting mechanism is arranged on a non-display surface of the flexible screen, the guide part is one of a rib and a chute, and the supporting mechanism is provided with the other of the rib and the chute.

17. A mobile terminal, comprising the foldable display device according to claim 13.

18. A mobile terminal, comprising the foldable display device according to claim 14.

19. A mobile terminal, comprising the foldable display device according to claim 15.

20. A mobile terminal, comprising the foldable display device according to claim 16.
